(19) United States
(12) Patent Application Publication
(10) Pub. No.: US 2025/0120218 A1
(43) Pub. Date: Apr. 10, 2025

(54) VEHICLE ROOF SOLAR PANEL WITH A VARIABLE DIMMING FEATURE

(71) Applicant: FCA US LLC, Auburn Hills, MI (US)

(72) Inventor: Daniel Bellmore, East Lansing, MI (US)

(21) Appl. No.: 18/481,053

(22) Filed: Oct. 4, 2023

(51) Int. Cl. H01L 31/0216; B62D 25/06; H01L 31/048; H01L 31/07

(52) U.S. Cl. CPC H10F 77/311; B62D 25/06; H10F 19/804; H10F 10/18

(57) ABSTRACT

Disclosed is a vehicle roof panel formed as a multilayer laminate having an outer shield layer, one or more solar cell laminate layers, and an internal electrochromic layer. The shield layer and the one or more solar cell laminate layers are transparent. The roof panel also may have a user controllable electrical input connected to the electrochromic layer whereby the user can adjust an electrical input to the electrochromic layer there by controlling its transparency from greater than 70% transparent to non-transparent. In the roof panel the one or more solar cell laminate layers are located between the shield layer and the electrochromic layer. The roof panel provides a convenient way to charge the batteries of electric vehicles and hybrid electric vehicles while allowing for user controllable dimming of the roof panel.

### FIELD

The present disclosure relates to a vehicle roof solar panel that has a variable, user controllable, dimming feature.

### BACKGROUND

With the increase in Electric Vehicles (EVs) and Hybrid Electric Vehicles (HEVs) it has been found that consumers want more range and easier charging of the vehicles. One way to accomplish this would be to add solar panels to the vehicle roof to add charging capacity. Past solar panel design has made this esthetically impractical as consumers do not want to see a clunky, dark colored solar panel mounted on top of a roof of their vehicle and this also adds considerable weight and complexity to the vehicle design. Standard solar panels would also require frequent replacement over the projected vehicle lifespan and they have not had very high efficiency making this an impractical solution.

Consumers enjoy having an open and airy feeling in their vehicle and a standard solid metal roof does not allow for this. Thus, sun roofs and moon roofs are popular with consumers. Some vehicles include a roof that is almost entirely glass and these are also popular with many consumers. One draw back is the inability to adjust the color/tint of these roofs on demand by the consumer.

### SUMMARY

In at least some implementations, a vehicle roof panel comprises a multilayer laminate having a shield layer, a solar cell laminate, and an electrochromic layer; at least one electrical connection electronically connected to the solar cell laminate; a user controllable electrical input connected to the electrochromic layer whereby the user can adjust an electrical input to the electrochromic layer; and wherein the solar cell laminate is located between the shield layer and the electrochromic layer in the multilayer laminate.

In at least some implementations, a vehicle roof panel comprises a multilayer laminate having a shield layer, a plurality of solar cell laminate layers, and an electrochromic layer; at least one electrical connection electronically connected to the plurality of solar cell laminate layers; a user controllable electrical input connected to the electrochromic layer whereby the user can adjust an electrical input to the electrochromic layer; and wherein the plurality of solar cell laminate layers are located between the shield layer and the electrochromic layer in the multilayer laminate and the shield layer and the plurality of solar cell laminate layers have a transparency of at least 70% to visible light in the range of 450 nanometers to 650 nanometers.

Further areas of applicability of the present disclosure will become apparent from the detailed description, claims and drawings provided hereinafter. It should be understood that the summary and detailed description, including the disclosed embodiments and drawings, are merely exemplary in nature intended for purposes of illustration only and are not intended to limit the scope of the invention, its application or use. Thus, variations that do not depart from the gist of the disclosure are intended to be within the scope of the invention.

### BRIEF DESCRIPTION OF THE DRAWINGS

FIG. 1 shows a roof panel design including a laminate having a shield layer, a transparent solar cell laminate and an electrochromic layer;

FIG. 2 shows the shield layer, transparent solar cell laminate design suitable for use in the roof panel, and the electrochromic layer;

FIG. 3 shows a schematic design of an electrochromic layer in the roof panel; and

FIG. 4 shows a schematic design of the roof panel and a roof trim covering the electrical connections.

### DETAILED DESCRIPTION

Current vehicle solar panels occupy much of the roof area and are not transparent leaving the occupants with a closed in feeling in the vehicle. Thus, it is desirable to provide a solar roof panel covering a portion or all of the roof that still allows for transmission of light through the roof and into an interior of the vehicle. Additionally, it would be beneficial if the solar panel could be darkened when desired by a vehicle occupant. The present disclosure provides such a roof panel.

Presently, automotive glass is manufactured into two different types of safety glass depending on its location in the vehicle. Automotive windshield glass is a laminated glass, automotive glass for the side and rear windows is tempered glass. Laminated glass is designed to prevent penetration of UV light through the glass. The glass used in automotive applications must meet many federal safety regulations including those from the National Highway Traffic Safety Administration (NHTSA) and the Federal Motor Vehicle Safety Standards (FMVSS). For example, FMVSS 205 regulates automotive window transparency and strength to provide safety during accidents. FMVSS 212 regulates the windshield mounting standards to ensure sufficient windshield retention in the event of an accident. FVMSS 216 regulates roof rigidity in the case of a rollover accident. Finally, FMVSS 219 states that no part of most passenger vehicles can penetrate the windshield more than 6 millimeters in a crash. All of these regulations influence what the disclosed vehicle roof solar panel with variable dimming feature of the present disclosure must be capable of doing to be an accepted solution.

Throughout the present specification and claims various materials will be referred to as transparent, this means that they allow for at least 70% transmission of visible light in the range of 450 nanometers to 650 nanometers to pass through the material at the thickness of the material that is used, and in some implementations greater than 75% transmission and in some implementations greater than 80% transmission.

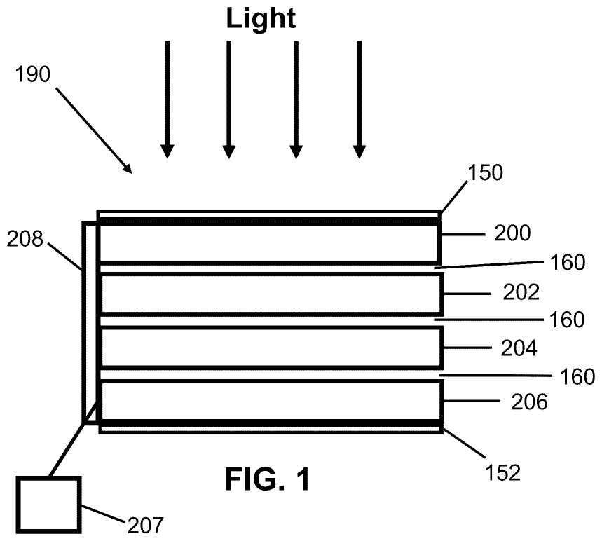

An embodiment of the vehicle roof solar panel with a variable dimming feature is shown generally at 190 in FIG. 1. The roof panel 190 includes a shield layer 200 that is transparent and serves to protect the roof panel 190. This shield layer 200 may, optionally, be covered with a protective coating 150 that is transparent and may serve as an antireflective barrier and provide scratch resistance to the shield layer 200. In at least some implementations, the coating 150 may define an outer surface of the roof panel 190.

Beneath the shield layer 200 is a first solar cell laminate 202 that is transparent, and in at least some implementations, there is also a second solar cell laminate 204 that is also transparent and is located beneath the first solar cell laminate 202. The solar cell laminates 202 and 204 are commercially available, each are composed of multiple layers, and described further below. The solar cell laminates 202, 204 absorb ultraviolet light in the range of 200 nm to 450 nm and near-infrared light in the range of 650 nm to 1400 nm while allowing for at least some visible light in the range of 450 nm to 650 nm to pass through.

Below the solar cell laminates 202, 204 is an electrochromic layer 206. This layer 206 varies in its light transmission properties depending on the electrical charge put into the electrochromic layer 206. Such electrochromic layers 206 are known in the art and they can have transparencies ranging from greater than 85% to 0% depending on the electrical charge status of the electrochromic layer 206. The electrochromic layer 206 thus is capable of variable dimming and the dimming level can be controlled by a user by varying the electrical charge applied to the electrochromic layer 206 which may be done via a suitable control interface 207. The control interface 207 may include one or more of a dial or slide input movable to progressively increase or decrease the dimming level, a series of buttons or other inputs each associated with a different dimming level, or a software interface presented on a screen of a vehicle infotainment system and by which a dimming level may be selected.

Along the side edges of the roof panel 190 are electrical connections 208. These can surround the entire roof panel 190 or be spaced apart. These electrical connections 208 serve to route the electrical energy generated by the first and second solar cell laminates 202, 204. They can also be used to provide electrical power from an exterior source or from the solar cell laminates 202, 204 to the electrochromic layer 206 to control its status.

A transparent adhesive 160 is located between the layers of the roof panel 190 as shown to secure the layers 200, 202, 204, and 206 into the final roof panel 190 structure. Such transparent adhesive 160 layers are very thin. The transparent adhesives 160 are temperature and pressure activated and they are activated during assembly and formation of the roof panel 190. Such transparent adhesives are known in the art and will not be further described. Finally, a second, optional protective coating 152 can be applied to the side of the electrochromic layer 206 facing the interior of the vehicle. It is also transparent and may provide an antireflective barrier and scratch resistance to the interior surface of the roof panel 190. Once the roof panel 190 layers as shown in FIG. 1 are arranged and assembled the final laminate roof panel 190 is formed using heat and pressure as is known, for example, in the art of glass lamination. The thinness of the roof panel 190 means the heat and pressure required to activate the adhesives 160 and to form the roof panel 190 to shape are not as high as would be required for a thicker laminate. The roof panel 190 is formed to a profile to fit the vehicle it is designed for. This forming using pressure and heat activates the adhesives 160 and secures the layers 200, 202, 204, and 206 with protective coatings 150 and 152 together into the final roof panel 190.

In at least some implementations, the protective coatings 150, 152 comprise an acrylic coating. The shield layer 200 may be a polycarbonate or laminated polycarbonate panel having a thickness of from 1 millimeter to 2 millimeters, and in some implementations may be between 1.4 to 1.6 millimeters. The acrylic coating 150, 152 may be from 5/1000 of an inch to 10/1000 of an inch thick, 127 microns to 254 microns. Laminated polycarbonate panels can be 40% or more lighter than the same thickness of standard tempered automotive glass and over 200% stronger. The laminated polycarbonate panels, at the thicknesses used, may have the ability to stop point blank fired small arms fire and will deflect rocks and road hazards that may fall onto the roof panel 190. Acrylic and polycarbonate are both plastics, but they have different properties. Acrylic is shinier while polycarbonate is stronger. Both are much lighter than a comparable sized sheet of glass and much stronger than glass. Acrylic can be used as a coating material as in the present disclosure and it is very scratch resistant. It can also be formed into sheeted material. Acrylic is marketed under a variety of tradenames including Plexiglas® and Lucite®. It can provide a high-level of light transmittance (e.g. 80-95%) and this is higher than that of glass. In addition, it resists discoloration under UV light exposure and thus will protect the roof panel 190 from discoloration if used as the outer layer in the roof panel 190. Polycarbonate is marketed under a variety of tradenames including Lexan® and Makarolon®. It can be over 30 times as strong as acrylic and have 250 times the impact resistance of glass. In at least some implementations, it can have a light transmittance of 80-95%.

The disclosed roof panel 190 includes solar cell laminates 202, 204 that have an average visible light transmission value of 70% or greater and are suitable for use in the disclosed embodiments. These solar cell laminates 202, 204 have been created in several different ways by various manufacturers and investigators. Two different designs will be briefly described below, both being suitable for use in the present disclosed roof panel 190.

In one embodiment, the solar cell laminates include nanoparticle crystals applied to transparent substrates to create a Schottky-barrier solar cell, also known as a Schottky-junction solar cell. The transparent substrate material can be any transparent substrate including: glass, acrylic, polycarbonate, laminated polycarbonate, quartz and other transparent materials.

In a basic Schottky-barrier solar cell an interface between a metal and a semiconductor provides the band bending required for charge separation. They have been shown to generate power up to 1000 times more efficiently than traditional solar panels that rely on p-type and n-type semiconductor layers sandwiched together to form a p-n junction. In a typical solar cell there is a smooth band transition across the p-n junction; in a Schottky-barrier solar cell there is an abrupt potential difference due to differing energy levels between the Fermi level of the metal and the conductor band of the semiconductor. This abrupt potential difference is known as the Schottky height barrier.

These Schottky type solar cell laminates are created by controlling the contact barriers between an indium tin oxide (ITO) electrode, one of the most widely used transparent conducting oxides, and a monolayer of tungsten disulfide (WS₂) as the photoactive layer. The WS₂ is a transition metal di-chalcogenide. Transition metal di-chalcogenides like WS₂ exhibit excellent optoelectronic properties such as suitable bandgap, high absorption coefficient, good conductivity, and high carrier mobility, so they can be used as a photovoltaic material for thin-film solar cells. In addition, WS₂ is considered non-toxic and earth-abundant. In one solar cell design the contact barrier between the ITO electrode and WS₂ monolayer is controlled by coating one or more thin metals onto the layer of ITO (Mx/ITO), with M being the metal and x being its thickness in nanometers (nm), and inserting a thin layer, several nanometers thick, of tungsten oxide, WO₃, as an insulator between (Mx/ITO) and the monolayer WS₂, which results in an increase in the Schottky barrier height to increase the efficiency of the charge carrier separation in a Schottky-type solar cell. The WOs layer can be applied by thermal evaporation while the WS₂ monolayer can be applied using chemical vapor deposition.

A method of forming this embodiment was disclosed in a paper, Scientific Reports (2022) 12:11315, “Fabrication of near-invisible solar cell with monolayer WS₂” by Xing He et. al. and can be located online at https://doi.org/10.1038/s41598-022-15352-x. The produced solar cells with an electrode of (WO₃/Mx/ITO) have over 1000 times the power conversion efficiency of a normally constructed ITO electrode. By reducing the aspect ratio of (width/channel length) of the unit device to a value below a critical threshold of about 36 and with the appropriate number of series and parallel connections the investigators were able to produce a 1 cm² solar cell with a total power of up to 420 pW and an average visible light transmission of 79%. These solar cell designs are scalable and suitable for use in the present disclosure to form the first and second solar cell laminates 202, 204 of the roof panel 190.

To create the Schottky solar cell laminate according to the paper, a quartz substrate can be used as the transparent substrate and the ITO is sputtered onto the quartz substrate. Then the thin metal layer is applied. The thin metal layer (Mx), discussed above, can be provided by a number of metals including copper (Cu), nickel (Ni), iron (Fe), aluminum (Al), silver (Ag), and gold (Au) in thicknesses ranging from 1 to 5 nanometers. Copper is particularly effective in this design. This allows for creation of an electrode of (WO₃/Mx/ITO) having a Schottky barrier height of up to approximately 220 meV in contact with the WS₂ layer. Most of the electrodes created using these metals at these thicknesses onto a quartz substrate have an average light transmission of greater than 80%.

Other embodiments of transparent solar cell laminates are being commercially marketed by the company Ubiquitous Energy, Inc. of Redwood California. Their technology is explained in their many patents and published patent applications such as United States Patent Publication No. 2023/0172042. Their solar cell laminate designs are transparent, they absorb the ultraviolet light and near infrared light while allowing the visible light to pass through. The designs combine transparent electrodes with visibly transparent near-infrared absorbing photoactive compounds, optical materials and buffer materials.

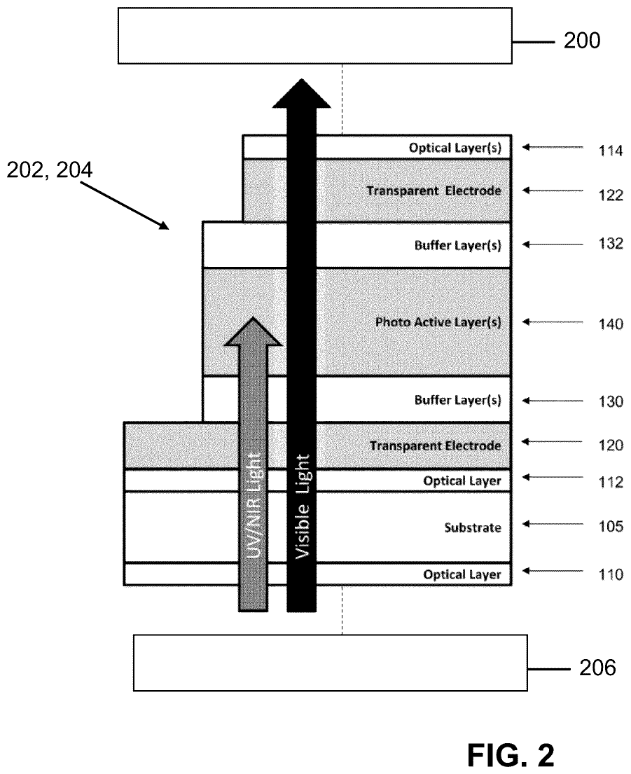

FIG. 2 shows an example of a transparent solar cell laminate design with the shield layer 200 and electrochromic layer 206 diagrammatically shown. In at least some implementations, the solar cell laminate 202, 204 can be arranged as shown in FIG. 1a from United States Publication No. 2023/0172042. The solar cell laminate 202, 204, called a visibly transparent photovoltaic device in the reference, has a plurality of layers and it absorbs light in the ultraviolet range of 200 nm to 450 nm and the near-infrared region of 650 nm to 1400 nm while allowing visible light in the range of 450 nm to 650 nm to pass through as shown in FIG. 2. A visibly transparent substrate 105, such as glass, polycarbonate or acrylic supports optical layers 110 and 112. The optical layers 110, 112 can provide a variety of effects including antireflection. An additional optical layer 114 can also be included. The solar cell laminate 202, 204 includes at least two transparent electrodes 120, 122 as have been described herein such as the Mx/ITO electrode described above with a thin metal layer of copper, aluminum, nickel, silver, iron, or gold. At least one photo active layer 140 is located between the electrodes 120, 122. As described in this reference these photo active layers 140 can be formed from boron-dipyrromethene-based compounds and structurally related compounds. The buffer layers 130, 132 can be formed from many materials including as described above WO₃ and other metal oxides, fullerene materials, carbon nanotube material, graphene material, polymers such as poly(3,4-ethylenedioxythiophene), polystyrene sulfonic acid and polyanilines as described in US Pub. No. 2023/0172042.

All of these layers can be applied by a variety of vacuum deposition techniques as described in US Pub. No. 2023/0172042 to result in the visibly transparent solar cell laminate including atomic layer deposition, chemical vapor deposition, thermal evaporation, physical vapor deposition, sputter deposition, and epitaxy. Although the particular reference, US Pub. No. 2023/0172042 describes the photo active layers 140 can be formed from boron-dipyrromethene-based compounds and structurally related compounds, as known to one of skill in the art there are other available transparent solar cell laminates using other photo active compounds.

The solar cell laminates 202, 204 are not limited to those described above, as they serve as examples of commercially available solutions, any transparent solar cell laminate may find use in the presently disclosed roof panel 190 embodiments. The embodiment shown in FIG. 1 of the present disclosure is shown with a first and a second solar cell laminate 202, 204, but could include any number of solar cell laminate layers as desired. Each solar cell laminate 202, 204 may have a thickness of from 1.5 millimeters to 2.5 millimeters, such as from 1.6 to 2.4 millimeters.

The electrochromic layer 206 is often known as “active smart glass” and is commercially available from a variety of manufacturers. The color and light transmittance of the electrochromic layer 206 is controlled by and can be changed by altering an electrical input into the electrochromic layer 206. It can be varied from clear, which allows for maximal light transmission, to a solid color, with the color determined by the electrochromic materials used to create the electrochromic layer 206. In the solid color state it can have very low light transmittance such as 10% or below, including zero light transmittance. The electrochromic material can be selected to match the color of the vehicle exterior, such as the area of the roof adjacent to the roof panel 190, when in the solid color form.

The “active smart glass” is created by laminating or spray applying a film of one or more layers of an electrochromic material onto a substrate such as glass, acrylic, polycarbonate, or laminated polycarbonate to form the electrochromic layer 206. In at least some implementations, the electrochromic layer 206 has a thickness of from 1 millimeter to 2 millimeters and may be between 1.4 to 1.6 millimeters, the majority of this thickness is made up of the substrate as the actual electrochromic material, transparent electrodes, and other components of the electrochromic layer 206 are very thin layers.

The electrochromic material is responsive to electric pulses sent to the material and changes its color/tint according to the received electric pulses. It maintains the color until receiving another electric pulse. Thus, it is low energy requiring as the state is maintained without further input. The electrochromic layer 206 utilizes transparent electrodes such as the ITO electrodes discussed above to provide power to the electrochromic material and include an electrolyte gel. In many electrochromic films the layers are porous nanocrystalline films of several stacked layers. These stacked layers include adsorbed chromogens or dyes whose color is determined by their redox state. The chromogens or electrochromic materials include materials from the transition metal oxides, the Prussian Blue system, Viologens, conductive polymers, and rare-earth metals by way of example. The Prussian Blue system includes: Prussian blue, nickel-substituted Prussian blue, Prussian brown, Prussian green, and Prussian white. The transition metal oxides include: WO₃, MoO₃, V₂O₅, TiO₂, Nb₂O₅, Ir(OH)₃, and NiO. The viologens are derivatives of 3-aryl-4,5-bis(pyridine-4-yl) oxazole. The conductive polymers include: Poly(3,4-ethylenedioxythiophene) (PEDOT), polypyrrole, polythiophenes, and polyaniline. Thus, electrical impulses can be used to change the color and or transmittance of the electrochromic layer 206.

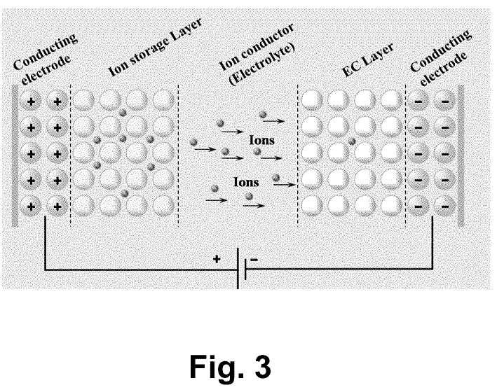

A schematic of one embodiment of a suitable electrochromic layer 206 is shown in FIG. 3. The structure shown in FIG. 3 can be placed between two polycarbonate sheets to form the electrochromic layer 206 or coated onto a single polycarbonate sheet to form the electrochromic layer 206. The movement of electrons changes the redox state of the electrochromic material (EC) and thus the color and/or transmittance of the electrochromic layer 206. Some electrochromic responsive designs utilize movement of lithium ions in transition metal oxides such as tungsten oxide. Other designs utilize a variety of chromogens to provide a range of colors to the electrochromic layer 206. The other use of the electrochromic layer 206 in the disclosed roof panel 190 is that it can be used to reflect any ultraviolet light or near-infrared light that gets through the solar cell laminates 202, 204 back into them for further harvesting of solar power.

The roof panel 190 through the electrical connections 208 provides an electrical connection to the electrochromic layer 206. The electrical connections 208 can be used to control the electric impulses to the electrochromic layer 206 via a user operable control 207. The electrical power can be provided from the roof panel 190 solar cell laminates 202, 204 or from a vehicle source such as a vehicle battery, capacitor or alternator. A user operable control 207 permits a user to vary the electrical power to the electrochromic layer 206, thus allowing the user to determine the color and/or transmittance level of the electrochromic layer 206. In this way a user can vary the transmittance between maximum and minimum levels, and all or various ranges in between, in at least some implementations.

The roof panel 190 includes along its edges electrical connections 208. These are formed of electrically conductive material such as metallic foil. The most common foils being copper. The electrical connections 208 can either be around the entire edge of the roof panel 190 or they can be spaced apart. The electrical connections 208 are used to move the captured electricity from the solar cell laminates 202, 204 out of the roof panel 190 and to pass electricity through to the electrochromic layer 206.

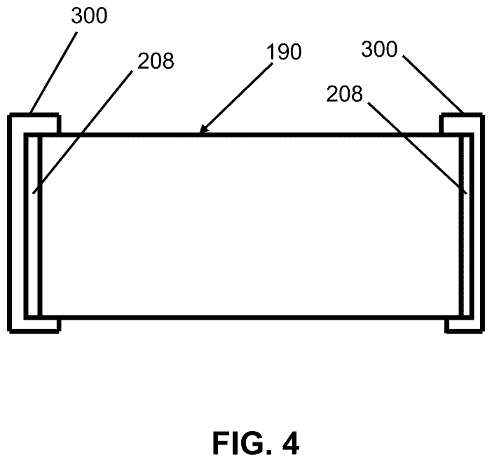

The roof panel 190 can be designed to cover the entire roof area of a vehicle or any portion thereof. The larger the roof panel 190 the more solar energy it may be capable of capturing. The shield layer 200, protective layers 150, 152, and solar cell laminates 202, 204 are all transparent as defined herein, and the electrochromic layer has a variable transmittance, as described herein. As shown in FIG. 4, in one embodiment the roof panel 190 covers the entire roof area, shown in cross-section in FIG. 4, and the electrical connections 208 are located under a roof panel trim 300 that secures it to the vehicle to make the roof appear as a solid sheet of material. The roof panel 190 and the associated components may all be solid state devices the maintenance issues are expected to be minimal. The roof panel 190 will provide a vehicle with a reduced weight compared to a metal roof panel. The electrical energy generated by the solar cell laminates 202, 204 can be used to charge an energy storage device of an EV or HEV that the roof panel 190 is mounted on, or to provide power for electrical devices/systems of the vehicle. Additionally, as discussed, the electrical power from the solar cell laminates 202, 204 can be used to power the electrochromic layer 206.

What is claimed is:

1. A vehicle roof panel comprising:
a multilayer laminate having a shield layer, a solar cell laminate, and an electrochromic layer;
at least one electrical connection electronically connected to said solar cell laminate;
and
wherein said solar cell laminate is located between said shield layer and said electrochromic layer in said multilayer laminate.

2. The vehicle roof panel according to claim 1, further comprising a protective coating on at least one of said shield layer, said electrochromic layer, or both.

3. The vehicle roof panel according to claim 2, wherein said protective coating comprises acrylic.

4. The vehicle roof panel according to claim 1, wherein said shield layer comprises a polycarbonate.

5. The vehicle roof panel according to claim 1, wherein said solar cell laminate is a Schottky-barrier solar cell.

6. The vehicle roof panel according to claim 1, wherein said solar cell laminate has a transparency of at least 70% to visible light in a range of 450 nanometers to 650 nanometers.

7. The vehicle roof panel according to claim 1, further comprising a transparent adhesive layer between said shield layer and said solar cell laminate and a transparent adhesive layer between said solar cell laminate and said electrochromic layer.

8. The vehicle roof panel according to claim 1, wherein said shield layer has a thickness of from 1 to 2 millimeters.

9. The vehicle roof panel according claim 1, wherein said solar cell laminate has a thickness of from 1.5 to 2.5 millimeters.

10. The vehicle roof panel according claim 1, wherein said electrochromic layer has a thickness of from 1 to 2 millimeters.

11. The vehicle roof panel according to claim 1, which also comprises a user controllable electrical input coupled to the electrochromic layer and by which a variable electrical input can be provided to the electrochromic layer.

12. A vehicle roof panel comprising:
a multilayer laminate having a shield layer, a plurality of solar cell laminate layers, and an electrochromic layer having a transparency that varies as a function of electrical power applied to the electrochromic layer;
at least one electrical connection electronically connected to said plurality of solar cell laminate layers to receive electricity generated in the solar cell laminate layers, and at least one electrical connection electrically connected to said electrochromic layer to provide electrical power to said electrochromic layer;
and
wherein said plurality of solar cell laminate layers are located between said shield layer and said electrochromic layer in said multilayer laminate and said shield layer and said plurality of solar cell laminate layers have a transparency of at least 70% to visible light in the range of 450 nanometers to 650 nanometers.

13. The vehicle roof panel according to claim 12, further comprising a protective coating on at least one of said shield layer, said electrochromic layer, or both.

14. The vehicle roof panel according to claim 13, wherein said protective coating comprises acrylic.

15. The vehicle roof panel according to claim 12, wherein said shield layer comprises a laminated polycarbonate.

16. The vehicle roof panel according to claim 12, wherein one or more of said plurality of solar cell laminate layers is a Schottky-barrier solar cell.

17. The vehicle roof panel according to claim 12, further comprising a transparent adhesive layer between said shield layer and one of said plurality of solar cell laminate layers, a transparent adhesive layer between each of said plurality of solar cell laminate layers, and a transparent adhesive layer between one of said plurality of solar cell laminate layers and said electrochromic layer.

18. The vehicle roof panel according to claim 12, wherein said shield layer has a thickness of from 1 to 2 millimeters.

19. The vehicle roof panel according claim 12, wherein each of said plurality of solar cell laminate layers has a thickness of from 1.5 to 2.5 millimeters.

20. The vehicle roof panel according claim 12, wherein said electrochromic layer has a thickness of from 1 to 2 millimeters.
